(19) United States
(12) Patent Application Publication
(10) Pub. No.: US 2014/0353583 A1
(43) Pub. Date: Dec. 4, 2014

(54) POLARIZATION INDEPENDENT PHOTODETECTOR WITH HIGH CONTRAST GRATING AND TWO DIMENSIONAL PERIOD STRUCTURE

(71) Applicants: THE REGENTS OF THE UNIVERSITY OF CALIFORNIA, Oakland, CA (US); BANDWIDTH10, INC., San Jose, CA (US)

(72) Inventors: Connie Chang-Hasnain, Palo Alto, CA (US); Li Zhu, Richmond, CA (US); Weijian Yang, Berekely, CA (US); Christopher Chase, Kensington, CA (US); Yi Rao, Albany, CA (US); Michael Chung-Yi Huang, North Caldwell, NJ (US)

(73) Assignees: BANDWIDTH10, INC., San Jose, CA (US); THE REGENTS OF THE UNIVERSITY OF CALIFORNIA, Oakland, CA (US)

(21) Appl. No.: 14/290,592

(22) Filed: May 29, 2014

Related U.S. Application Data
(60) Provisional application No. 61/828,796, filed on May 30, 2013.
(60) Provisional application No. 61/828,810, filed on May 30, 2013.

(51) Int. Cl. H01L 31/0352; H01L 31/0304; H01L 31/11; H01L 31/0232

(52) U.S. Cl. CPC H01L 31/035236; H01L 31/02327; H01L 31/0304; H01L 31/035272; H01L 31/11
USPC 257/14

(57) ABSTRACT

A photodetector is provided with a high contrast grating (HCG) reflector first reflector that has a two dimensional periodic structure. The two dimensional structure is a periodic structure that is a symmetric structure with periodic repeating. The symmetrical structure provides that polarization modes of light are undistinguishable. A second reflector is in an opposing relationship to the first reflector. A tunable optical cavity is between the first and second reflectors. An active region is positioned in the cavity between the first and second reflectors. The photodetector is polarization independent. An MQW light absorber is included converts light to electrons.

### CROSS-REFERENCE TO RELATED APPLICATIONS

This application claims priority to, and the benefit of, U.S. provisional patent application Ser. No. 61/828,796 filed on May 30, 2013, incorporated herein by reference in its entirety, and U.S. provisional patent application Ser. No. 61/828,810 filed on May 30, 2013, incorporated herein by reference in its entirety.

### STATEMENT REGARDING FEDERALLY SPONSORED RESEARCH OR DEVELOPMENT

Not Applicable

### INCORPORATION-BY-REFERENCE OF COMPUTER PROGRAM APPENDIX

Not Applicable

### BACKGROUND

1. Technical Field

The present invention is directed to tunable photodetectors, and more particularly to a high contract grating tunable resonance photodetector.

2. Background Discussion

A tunable photodetector is an important optical component and has a wide range of applications including but not limited to, optical communications, medical diagnostics, biochemical sensing, environmental monitoring, industrial processes control, defense, and the like.

Specifically, a monolithically integrated tunable photodetector is desirable due to its small footprint, and low energy consumption. In addition, it is desirable to have large tuning range, narrow spectral width, high responsivity, high detection speed and high tuning speed. Intensive research efforts have been devoted to this field, and various monolithically integrated tunable photodetectors have been reported. However, the tuning range is neither too small, or the spectral linewidth is too broad.

There is a need for a broadly tunable photodetector for optical communications applications, in particular WDM PON. There is a further need for a photodetector that can be tuned quickly on the order of μs for optical communications systems in data centers.

### BRIEF SUMMARY

An object of the present invention is to provide a broadly tunable photodetector.

Another object of the present invention is to provide a broadly tunable photodetector for optical communications applications.

Yet another object of the present invention is to provide a broadly tunable photodetector for WDM PON applications.

Still another object of the present invention is to provide a photodetector that can be tuned quickly on the order of μs for optical communications systems in data centers.

These and other objects of the present invention are achieved in, a photodetector with a high contrast grating (HCG) reflector first reflector that has a two dimensional periodic structure. The two dimensional structure is a periodic structure that is a symmetric structure with periodic repeating. The symmetrical structure provides that polarization modes of light are undistinguishable. A second reflector is in an opposing relationship to the first reflector. A tunable optical cavity is between the first and second reflectors. An active region is positioned in the cavity between the first and second reflectors. The photodetector is polarization independent. An MQW light absorber is included converts light to electrons.

Further aspects of the technology will be brought out in the following portions of the specification, wherein the detailed description is for the purpose of fully disclosing preferred embodiments of the technology without placing limitations thereon.

### BRIEF DESCRIPTION OF THE SEVERAL VIEWS OF THE DRAWING(S)

FIGS. 1A through 1D illustrate embodiments of a photodetector of the present invention that includes at least one high contrast grating (HCG) reflector.

FIG. 2 is a top view of one and two dimension of HCG reflectors used in certain embodiment of the present invention.

FIG. 3A is a top view of two dimensional HCG reflectors in a non-connected domain in one embodiment of the present invention.

FIGS. 3B and 3C are schematics of a whole HCG tunable resonance cavity photodetector in certain embodiments of the present invention.

FIG. 4A illustrates one embodiment of a two dimensional HCG reflector with a different shape of high index grating bar shapes in certain embodiments of the present invention.

FIG. 4B illustrates a two dimensional HCG reflector with a hexagonal spatial periodicity in one embodiment of the present invention.

FIG. 4C illustrates one embodiment of an apodized HCG reflector to achieve spatial mode engineering.

FIG. 5 illustrates examples of the reflection spectrum of HCG and DBR reflectors that can be used with the present invention.

FIG. 6 illustrates a limit of a photodetector responsivity for a Fabry-Perot cavity 16 with a second reflector of 99.9% at 1.55 μam optical wavelength, in one embodiment of the present invention.

FIG. 7 illustrates an embodiment of the present invention with the photodetector responsivity and the cavity quality factor corresponding to a round trip absorption, in one embodiment of the present invention.

FIG. 8 illustrates a photodetector responsivity at different reverse bias voltages, in certain embodiments of the present invention.

FIG. 9 illustrates a responsivity spectrum of a photodetector under different tuning conditions, in one embodiment of the present invention.

FIG. 10 is an eye diagram of a photodetector at 2.5 Gbps, in one embodiment of the present invention.

### DETAILED DESCRIPTION

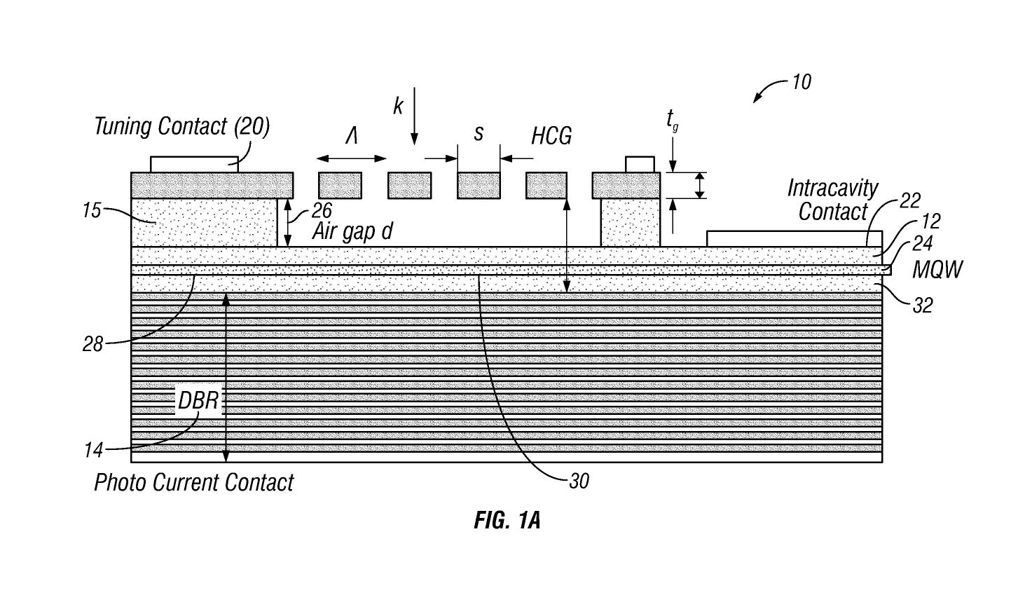

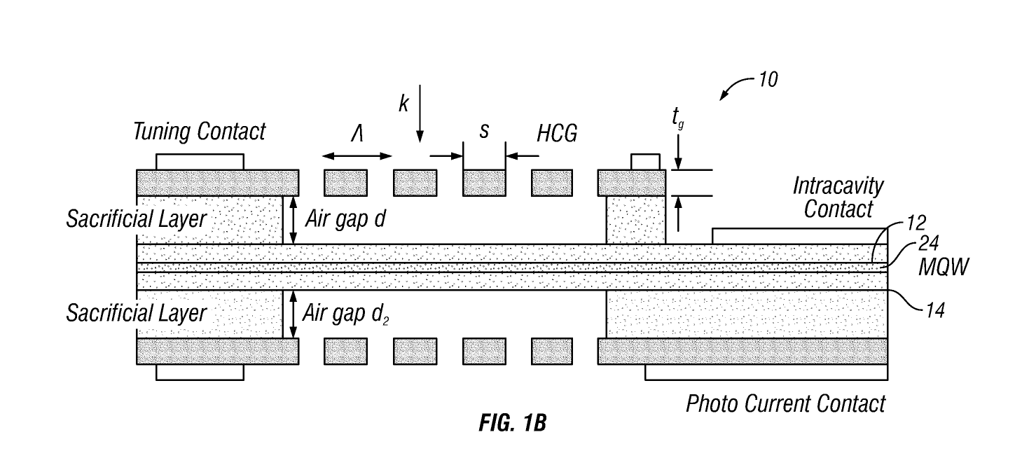

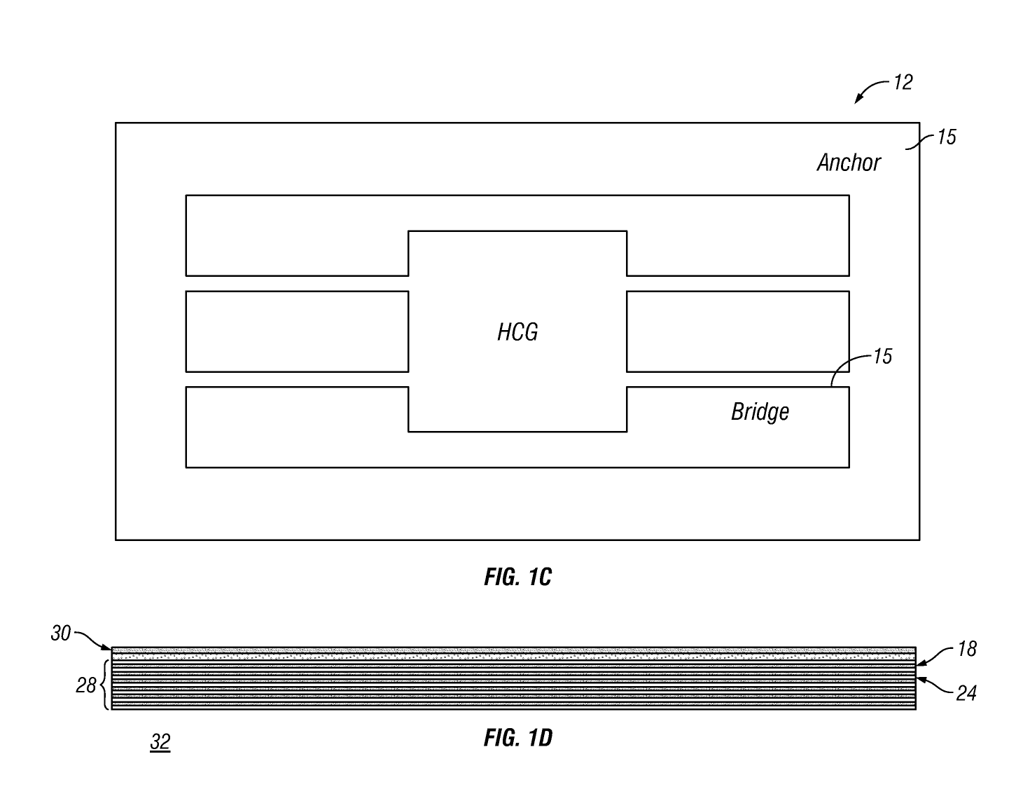

As illustrated in FIGS. 1A through 1D, the present invention provides a photodetector 10 that includes a high contrast grating (HCG) reflector, a first reflector 12, and a second reflector 14 in an opposing relationship to the first reflector 12. A tunable optical cavity 16 is between the first and second reflectors 12 and 14. An active region 18 is in the cavity 16 between the first and second reflectors 12 and 14. Also included is a tuning contact 20, an intra-cavity contact 22, MQW 24 which can be a barrier. Further details regarding the MQW are described hereafter. An air gap d 26 is included.

In one embodiment, the first 12 or second reflector 14 when it is an HCG is acts and/or is a lens. Anchors and bridges 15 are provided as illustrated in FIG. 1C. Anchor's prevents the first reflector 12 from flying away. The first reflector 12 which has air gap 26 underneath and is connected to anchor areas by bridges 15. The bridges 15 can be replaced by cantilever, folded beam, comb drive, and other supporting mechanical structure, and the tunable function of 10 still maintains.

In one embodiment, the active region 18 is positioned in the cavity 16 at an optical field anti-node position in the cavity 16.

As non-limiting examples, the photodetector 10 is a tunable Fabry-Perot cavity and the first reflector 12 is electrostatically actable. Multiple quantum wells 28 can be the active region, placed at the optical field anti-node position in the cavity 16. In another embodiment, the active region 18 is a double heterostructure action region. The first reflector 12 is actuated by a light absorption structure.

As a non-limiting example, the HCGs of first reflector 12 or second reflector 14 can have broadband high reflectivity. In one embodiment, some of the components have the following designation: A, HCG period; s as a grating bar width; t_{g}, as an HCG thickness; d as the tunable air gap; and d₂ as the air gap for the second reflector 14 as an HCG.

In one embodiment, the second reflector 14 is a DBR. In other embodiments, the second reflector 14 is a semiconductor or dielectric DBR. The second reflector 14 can be a metal reflector and also an HCG, as recited above.

The first reflector 12 can be electrostatically actuatable. The active region 18 can function within the Fabry-Perot cavity 16 as a light absorbing layer. In one embodiment, the active region 18 is below the Fabry-Perot cavity 16 as a light absorbing layer. An embedded tunnel junction 30 can be placed inside the cavity 16 to remove p-doped materials, to reduce free-carrier absorption. The tunnel junction 30 can be placed at a node of the optical cavity 16 to minimize its overlap with the optical field.

In various embodiments, the active region 18 can be on a substrate of GaAs, InP, GaN, GaP, Si, glass, sapphire, and any substrate suitable for epitaxial growth.

In various embodiments, the photodetector 10 can be used for a variety of applications, including but not limited to: in a WDM network to select wavelength of interest; in a PON; as an optical wave-meter; as a spectrometer; in medical diagnostics applications; for biochemical sensing applications; in industrial process control systems; in an environmental monitoring system; in concert with a TIA to provide an amplified signal; to recover an analog data signal; to recover a digital data signal; incorporated with at least one of, optical and electrical elements to calibrate a wavelength of the photodetector; to tune to either red or blue off its center wavelength, and the like.

In one embodiment of the present invention, the photodetector 10 is an ultra-compact monolithically integrated photodetector 10 with a high contrast grating tunable (HCG) Fabry-Perot cavity 16 with embedded quantum wells 28. As a non-limiting example, the high reflectivity and light weight of the high contrast grating HCG 12 enables a narrow spectral width and high tuning speed. As a non-limiting example, in one embodiment, the Fabry-Perot cavity 16 of the present invention provides a large tuning range of >30 nm, high responsivity of 1 A/W as well as high detection speed of 10 Gb/s. 30 nm.

In one embodiment, the photodetector 10 is broadly tunable (30-60+ nm) with a spectral line-width between 0.1 and 2 nm and a responsivity of ˜1 A/W for optical communications applications, in particular WDM PON. In another embodiment, the photodetector 10 can be tuned quickly on the order of μs for optical communications systems in data centers.

In one embodiment, the present invention is a photodetector 10 with high responsivity, close to 1 A/W. In another embodiment, the tunable photodetector 10 has a 0.5-2 nm spectral width across a tuning range of 30-60 nm. In another embodiment, the tunable photodetector 10 can be tuned at μs time scales.

In one embodiment, the optical Fabry-Perot cavity 16 is formed by the first and second reflectors 12 and 14 possessing high reflectivity. As a non-limiting example, the high reflection can be >: 90%, 95%, 99% and the like. In one embodiment, the first reflector 12, which is actuated by a MEMS structure 32, is designed with a high contrast grating (HCG), as recited above.

In one embodiment, the MEMS structure 32 is a cantilever or a bridge structure, and can be actuated in a variety of ways. As non-limiting examples, the actuation can be: electrostatically; piezo-electrically, thermally and the like.

In one embodiment, the first reflector 12, e.g., the HCG reflector, is a single layer of subwavelength grating with the grating bar made by the high index material and fully surrounded by the low index materials. As a non-limiting example, the low index material can be a high index material of InP and low index material of air. In one embodiment, the grating period is smaller than the optical wavelength in the low index material. As a non-limiting example, for 1550 nm light, the period is less than 1550 nm.

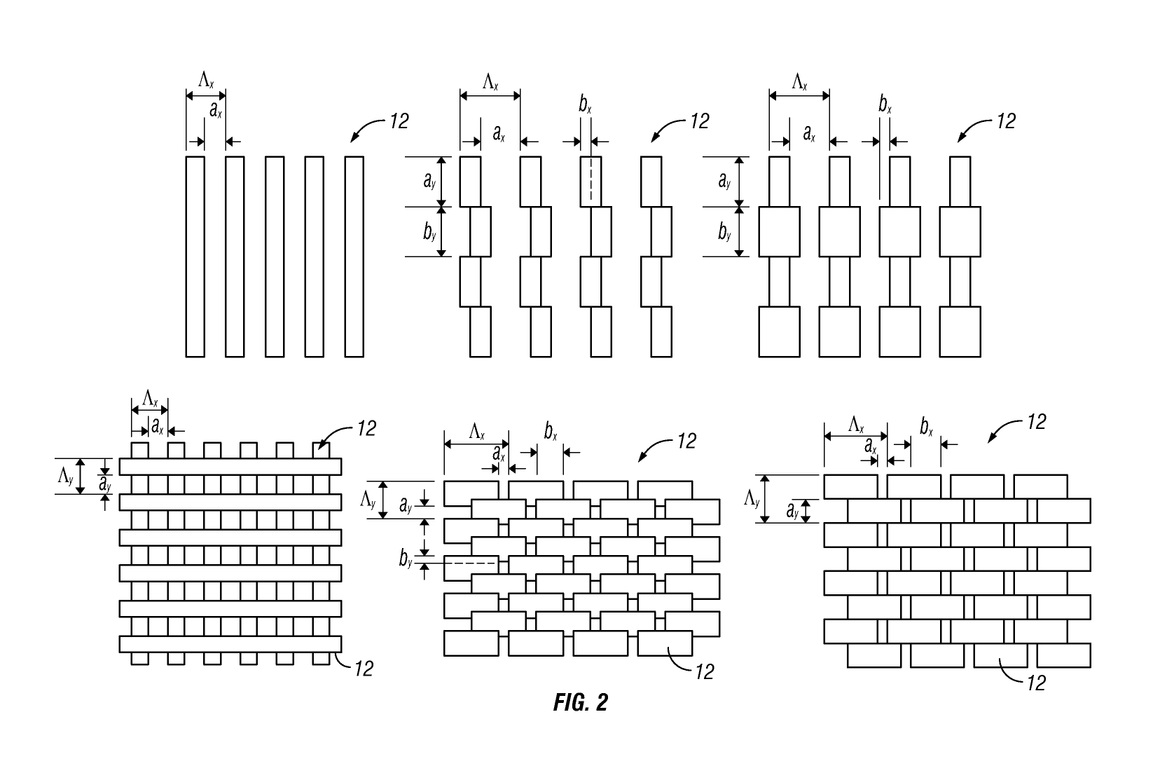

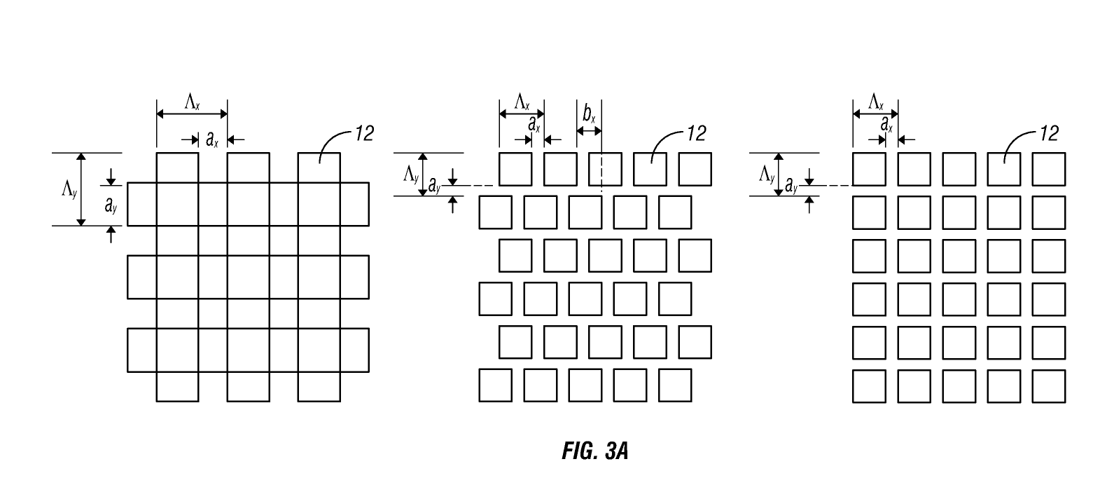

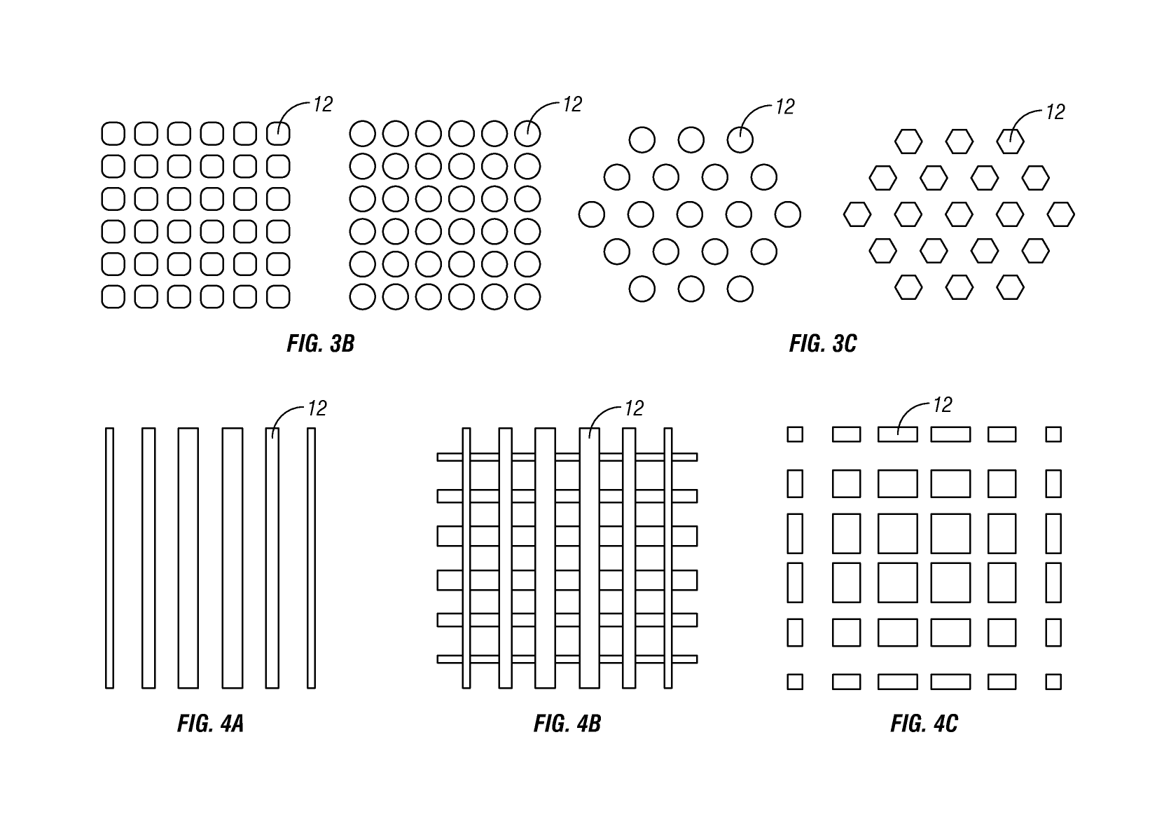

In one embodiment, the spatial periodicity of the HCG can be designed as one dimensional or two dimensional, as illustrated in FIGS. 2 and 3. The one dimensional embodiment can be polarization sensitive, in general; whereas the two dimensional embodiment IS symmetric and thus polarization insensitive in that the reflection of the grating is the same no matter what polarization is input on the grating due to its symmetry.

The (HCG) reflector first reflector 12 can be a two dimensional periodic structure. The two dimensional structure is a periodic structure that is a symmetric structure with periodic repeating, with the symmetrical structure providing that polarization modes of light are undistinguishable. The photodetector 10 is polarization independent.

In one embodiment, the MQW 24 is light absorber that converts light to electrons.

In one embodiment, the HCG reflector 12 has a 98 to 99 percent peak reflection

In one embodiment, the HCG reflector 12 has a peak reflection sufficient for detecting responsitivity. The higher the responsitivity the higher the conversion of light to electrons.

If the reflectivity is too high, incoming light is mostly reflected and the responsitivity is low. When the reflectivity is too low the cavity is too weak to contain the light and absorb the light and the responsivity is low.

In one embodiment, the HCG peak reflection is in the range of 98% to 99%, and a reflection bandwidth Δλ/λ is from 2% to 15%.

In one embodiment, the HCG 12 has a reflection band sufficient for band detection, at least one of: a full Cat 1530 to 1565 nm, a full L at 1565 to 1625 nm and a full S at 1460 to 1530 nm.

In one embodiment, the photodetector 10 has a sufficiently a signal to noise ratio to provide for detecting responsitivity. In one embodiment, detecting responsitivity is in the range of at least 0.5 A/W

In one embodiment, the active region # provides for sufficient absorption to be a detector with a responsitivity of at least 0.5 A/W.

In one embodiment, the sufficient absorption is achieved with an MQW 24 thickness of 6 to 12 nm.

In one embodiment, the active region includes an MQW 24 with a thickness of 6 to 12 nm.

In one embodiment, the photodetector 10 uses a reverse bias that is a negative voltage. A positive voltage is applied on a photo current contact and a negative voltage is applied on an intracavity contact.

In one embodiment, the photodetector detects light and converts photons to electrons with the MQW 24 absorbing light. Energy in the light is converted to separate electrons and holes that are collected by contact and form current.

In one embodiment, the first reflector 12 includes a one dimensional grid of materials, as illustrated in FIG. 2 which is a top view of one and two dimension first reflectors, e.g., HCG reflectors 12. In another embodiment, the first reflector 12 is a two dimension HCG reflector and includes a two dimensional grid of materials. The one dimensional case is generally polarization sensitive. The two dimensional case can be either symmetric to be polarization insensitive or asymmetric to be polarization sensitive. As a non-limiting example, Λₓ, Λ_{y} can be the grating periods in the two directions; and aₓ, a_{y}, bₓ, b_{y} are the other design parameters.

In one embodiment, the two dimensional first reflector 12, e.g., the HCG reflector, can have a variety of patterns. Non-limiting examples of such patterns include but are not limited to a: square grid; hexagonal grid, octagonal grid, grid of squares, grid of lines, and the like. In one embodiment, the lines can be somewhat offset between rows such as in a honeycomb pattern by any amount, arbitrarily offset and the like.

As non-limiting examples, FIG. 2 illustrates embodiments of the HCG structures with the grating bar being connected to the frame. The entire HCG can be fully released in that the grating itself is not bound to anything, fully surrounded by liquid, vacuum or a gas, or some medium that provides negligible mechanical resistance. This is a result of using a gas or fluid rather than a solid as a surrounding medium.

In one embodiment, the HCG is designed in a non-connected domain where the grating pieces are not connected to each other. In this embodiment, the grating pieces are attached to a low index membrane as shown in FIG. 3A. In this embodiment, a layer with low refractive index can be placed underneath the HCG as supports.

Referring now to FIG. 3A, a top view of a two dimensional HCG in non-connected domain is shown. A low refractive index layer can be added beneath the HCG as supports. Schematics of the whole photodetector 10, in this embodiment, are illustrated in FIGS. 3B and 3C. κₓ, Λ_{y} are the grating periods in the two directions. aₓ, a_{y}, bₓ are the other design parameters.

The shape of the unit period of the two dimensional HCG can vary from the examples in FIGS. 2 and 3A through 3C. Besides the rectangles in the connected and non-connected domain, other shapes can also be used. As non-limiting examples, such shapes can include: round-corner rectangle, circles, polygons, and the like, as illustrated in FIGS. 4A and 4B. These shapes are placed at some sort of subwavelength periodicity, where the period is less than the wavelength of interest. Additionally, besides the rectangular spatial periodical grid, the first reflector 12 can also follow other periodical grids, including but not limited to the hexagonal grid illustrated in FIG. 4B.

FIG. 4A illustrates an embodiment of a two dimensional first reflector 12 with different shape of the high index grating bar shapes. FIG. 4B illustrates a two dimensional first reflector 12 with a hexagonal spatial periodicity. FIG. 4C illustrates an example of an apodized first reflector 12 to achieve spatial mode engineering. In one embodiment, the first reflector 12 is made to provide the spatial mode by apodizing the grating to non-periodic. In this embodiment, the period of the grating of the first reflector 12 increases or decreases across the first reflector 12 in order to provide the desired output beam shape. As a non-limiting example, the laser output beam can be designed to be lensed, increasing or decreasing the beam angle of the laser. Non-limiting examples for one dimensional and two dimensional apodized structures are illustrated in FIG. 4C. The period and duty cycle can be changed at each unit period of the HCG. This can be used to achieve a lensing effect for example or even something more exotic such as an angled beam. It will be appreciated that when the second reflector 14 is an HCG reflector, it can also have the embodiments listed in this paragraph.

In one embodiment, the first reflector 12 is non-periodic to achieve a desired optical mode shape inside or outside of the cavity 16. As previously mentioned, the first reflector 12 can be polarization dependent or independent.

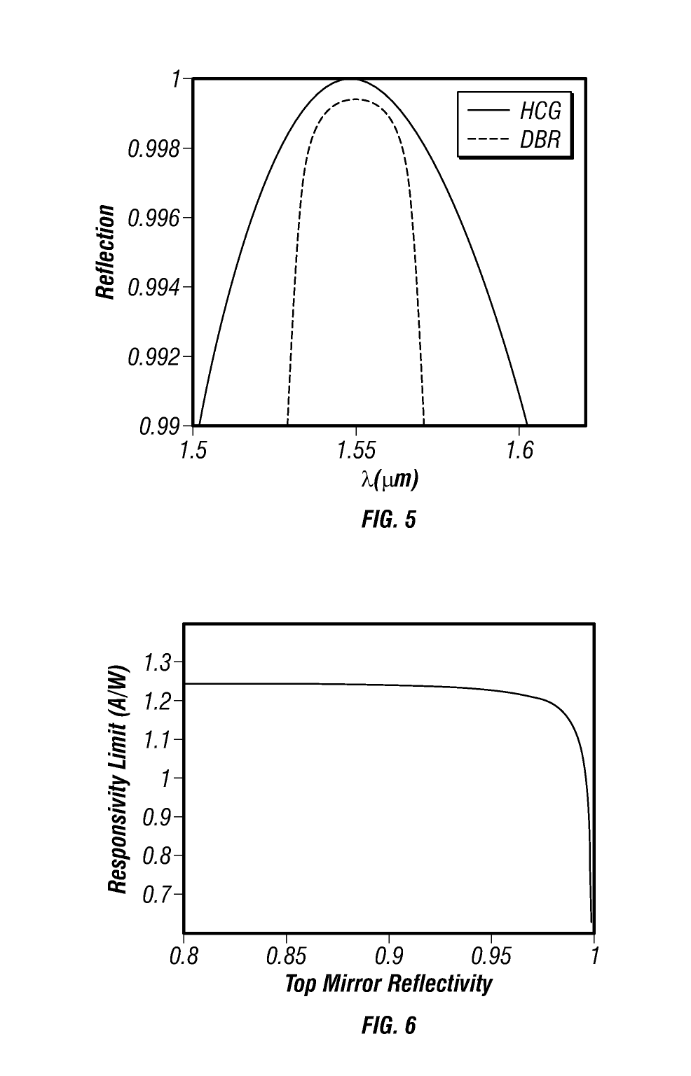

FIG. 5 illustrates examples of the reflection spectrum of first reflector as an HCG reflector 12, and second reflector 14 as a DBR. The first reflector 12 possesses the property to be an ultra-high reflection reflector 12 with the bandwidth broader than the conventional DBRs. As a non-limiting example, the first reflector 12 can be used to have a ΔLambda/Lambda of 35% with over 99.9% reflectivity.

As non-limiting examples, the DBR can be made of: semiconductor materials; dielectric materials; metal in combination with semiconductor or dielectric materials; metal; and the like.

As a non-limiting example, the reflection spectrum of the first reflector 12, with an HCG thickness of about 200 nm, is shown in FIG. 5. In this embodiment, the high reflection (R>0.99) band of the first reflector 12 is larger than 100 nm, while the second reflector 14, when it is a DBR reflector, based on an InP/AlGaInAs material system with 50 pairs, can only achieve 40 nm bandwidth. As non-limiting examples, the HCG thickness of the first reflector 12, or the second reflector 14 when it is an HCG reflector, can be 10 to 100 times smaller than this conventional DBR reflector. In one specific embodiment, it is 50 times smaller. Therefore, the mass of this first reflector 12, as an HCG reflector, is much lighter, which as non-limiting examples can be 100 to 10,000 times that of conventional DBRs, leading to a much faster tuning speed. As non-limiting examples, tuning speeds can range from 1 millisecond, 1 to 20 ns.

FIG. 6 illustrates a limit of the photodetector 10 responsivity for the Fabry-Perot cavity 16 with second reflector 14 of 99.9% at 1.55 μam optical wavelength. As shown in FIG. 6, the responsivity limit drops greatly when the first reflector 12 reflectivity approaches 1. In addition, the cavity 16 length is also an element in responsivity. A narrower spectrum width requires a longer cavity 16.

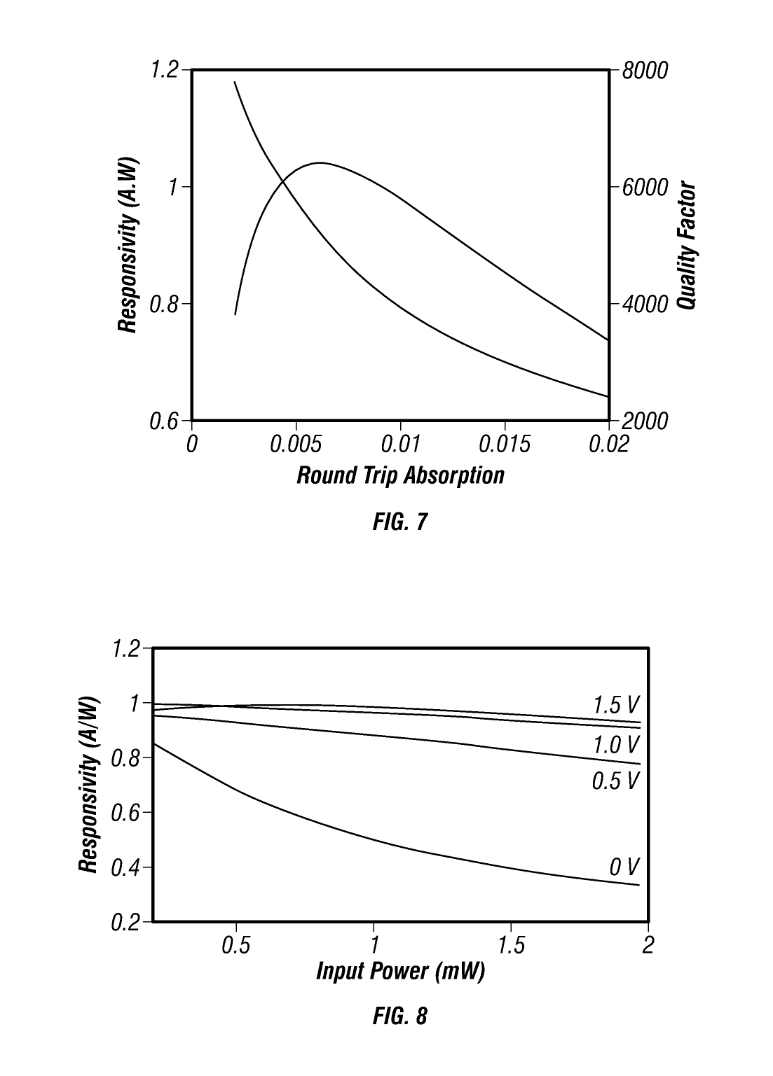

FIG. 7 illustrates the photodetector 10 responsivity and the cavity 16 quality factor corresponding to a round trip absorption with first reflector 12 reflectivity R1=99.5%, second reflector 14 reflectivity R2=99.9% and cavity 16 length L=10λ.

As a non-limiting example, FIG. 8 illustrates the photodetector 10 responsivity at different reverse bias voltages.

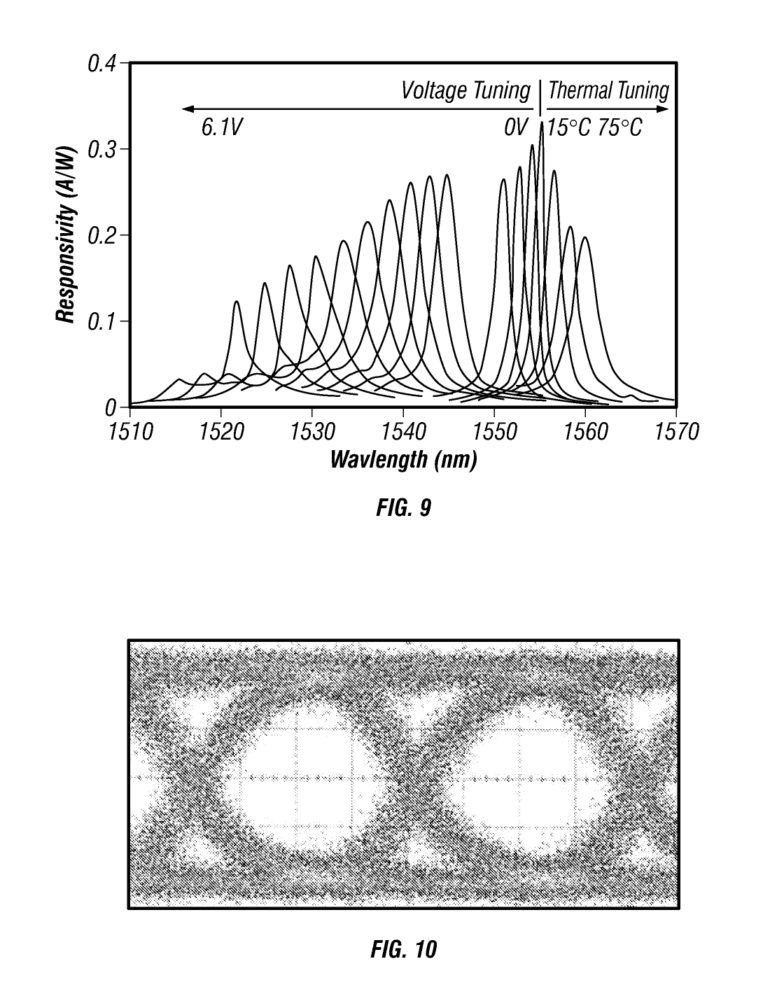

FIG. 9 illustrates the responsivity spectrum of the photodetector 10 under different tuning conditions, in one embodiment.

FIG. 10 is an eye diagram of the photodetector 10 at 2.5 Gbps.

In order to optimize for narrow line width, large tunability and responsivity, the first reflector 12 reflectivity and the cavity 16 length needs to be properly designed. In one embodiment, a 100 GHz DWDM grid has a line width of ˜0.8 nm, with a responsivity of ˜1 A/W. In one embodiment, a 50 GHz DWDM grid would has a line width of 0.4 nm, with a responsivity of ˜1 A/W. Narrowing the spectrum width requires that the loss of the cavity 16 be minimized.

Because the reflector loss is

$${α}_{m} = \frac{1}{L} ln \frac{1}{{R}_{1} {R}_{2}} ,$$

the cavity 16 needs to have second reflector 14 with a high reflectivity, and in one embodiment, its reflectivity is as high as possible. The second reflector 14 is the one that the light is not input through. It will be appreciated that the second reflector 14 can be the input reflector when it is an HCG reflector. In one embodiment, the reflectivity of the second reflector 14 is as close to 1 as possible, preferably >99.9%). However, the reflectivity of the first reflector 12, which can be the first or the second reflector, influences photodetector 10 responsivity and line-width in that if the reflectivity of the input (coupling) reflector is too high than the spectral line width of the tunable photodetector 10 can become smaller than desired and/or the responsivity too low.

For the consideration of the tunability, the cavity 16 is preferably short. As a non-limiting example, its length is 1 to 30 Lambda. The relationship between the wavelength tuning and the reflector displacement is

$$Δλ = \frac{2 n Δ x}{m} .$$

Δx is the reflector displacement from MEMS tuning and m is the number of the standing wave peaks inside the cavity 16, which is proportional to the cavity 16 length. In order to get a large Δλ, on the order of 30 nm or more, which is one of the limiting factors of the tuning range, m is can be, and in one embodiment is <30. The figure of merits, such as spectrum width, tunability and responsivity are trade-offs. As a non-limiting example, in order to achieve a very narrow line width of <1 nm the reflectivity of the first reflector 12 should be as high as possible, >99.9%. DBR pairs can be on top of the active region 18 to keep improving the first reflector 12 reflection. In one embodiment, to minimize the multi-reflection interference inside the cavity 16, an anti-reflection coating layer (i.e. a layer of material designed such that the overall interface reflection, which as non-limiting examples can be from <5% down to 0%, can be put inside the cavity 16. However, in both cases, the cavity 16 will be longer and the tunability or responsivity could be sacrificed. In one embodiment, a 100 GHz DWDM grid with a line width of ˜0.8 nm is desirable, with a tuning range of 32 nm (optical C band, at 1550 nm). As a non-limiting example, a 50 GHz DWDM grid requires a line width of ˜0.4 nm, with a tuning range of 32 nm (optical C band, at 1550 nm).

Inside the cavity 16, the optically absorbing material structure is embedded to absorb the injected photons and create the photocurrent. In order to reduce the p-type region, reduce the free carrier loss and lower the resistance, the tunnel junction 30 is embedded (the tunnel junction 30 can be made up of a degenerately doped p and n-doped materials which has an Ohmic behavior as the device is biased with a positive voltage going from the n to the p material). One embodiment of the cavity 16 layers is illustrated in FIG. 1.

As a non-limiting example, for photodetectors 10 designed for 1550 nm wavelength range, an example of the cavity 16 layers is designed based on InP/AlGaInAs material system. The active region 18, which includes the optically absorbing material structure, including but not limited to the quantum wells 28, is labeled as the “A:” layers and the barrier layers labeled as the “B” layers. As a non-limiting example, the barrier layers B can be made of AlGaInAs with different compositions, including but not limited to Al, Ga, In, and As could all be from 0 to 100% of the group III atoms in the material.

The tunnel junction is placed next to the optically absorbing material structure. The second reflector 14 is below the active region 18, which in one embodiment is made by InP/AlGaInAs DBR pairs. On top of the active region 18, a sacrificial layer is designed to release the first reflector 12. As a non-limiting example, the optical length can be 1 and 100 Lambda for the entire cavity 16 that is has an integer number of resonance wavelength for a round trip.

In order to achieve the best responsivity, the optically absorbing material structure is placed at the peak of the standing wave to get the maximum confinement factor. The material system can be changed based on the selection of the working wavelength range and the processing regulations. As non-limiting examples, material systems, such as GaAs/AlGaAs, InP/InGaAsP, and the like, can also be utilized.

The incidence light comes from the top of the first reflector 12 and/or the second reflector 14 when it is an HCG reflector. At Fabry-Perot cavity 16 resonance condition, light is injected into the cavity 16 and forms a standing wave. Once the standing wave peak is aligned with the optically absorbing material structure, injected photons are absorbed and create free carriers. With biased condition, these free carriers are collected and give photocurrent to the circuit.

In order to optimize the responsivity, the number of the quantum wells 28 in the active region 18 needs to be properly designed. As a non-limiting example, the number of quantum wells can be 1 to 20 The number of quantum wells 28 can be dependent on desired responsivity and the line width. As a non-limiting example, and as illustrated in FIG. 7, if the cavity has the first reflector reflectivity R₁=99.5%, second reflector 14 reflectivity R₂=99.9%, then the cavity 16 length can be 10 times of the resonance wavelength. The responsivity has an optimum point as regarding to the cavity 16 absorption, expressed as

$${e}^{- abso} = \frac{- abs \sqrt{{R}_{1} {R}_{2}} + {R}_{2}}{2 {R}_{2} + \sqrt{{R}_{1} {R}_{2}} ( 1 - {R}_{2} )} .$$

When the absorption is beyond the optimum point, the responsivity drops and the quality factor of the cavity 16 drops as well, which results in negative impacts to both of the aspects. If the absorption is smaller than the optimum point, the quality factor and the responsivity become the trade-off. Smaller absorption provides a higher quality factor, resulting in a narrow spectrum width. However, the responsivity is then reduced somewhat. In this embodiment, the number of the quantum wells 28 can be a parameter for such a trade-off.

To have lateral carrier confinement, proton implant, quantum intermixing, thermal oxidation, wet chemical etch, and the like, can be applied to define a current aperture.

In one embodiment, the MEMS structure 32 at this configuration is statically-electrically actuated. A p-n junction is between the tuning contact and the photocurrent contact. By applying a reversed bias voltage, the first reflector 12 and the photocurrent contact layer underneath form a capacitor. There is a static electrical force with this charged capacitor and it pulls the first reflector 12 closer to the active region 18. The optical length of the cavity 16 therefore becomes shorter and tunes the resonance to a bluer wavelength. The tuning speed of the MEMS structure 32 can be optimized by designing the size of the first reflector 12 and the spring constant, which is corresponding to the size of a cantilever supporting the HCG layer. A 27 MHz tuning speed is achieved with this embodiment.

The photodetector 10 can be reversed biased to efficiently collect the carriers generated by the photon absorption at the active region 18. In one embodiment, illustrated in FIG. 8, starting from 0V bias, the responsivity increases with higher reversed bias voltage. The trend saturates at 1.5V with responsivity achieving 1 A/W. Further increasing the voltage does not help to increase the photocurrent but give larger dark current, which is harmful to photodetector 10 sensitivity.

The electrical property of the photodetector 10 can be optimized for high speed communication applications, which as non-limiting examples can be with bit rates from 1-100+ Gbps.

The parasitic capacitance can be reduced by properly designing contacts on the top. To reduce parasitic capacitance, it is desirable to make this as small as possible. There is an optimization of the area of the photodetector 10. As a non-limiting example, the photodetector can have a range of 10-50 microns, 10-40 microns, 10-30 microns, and the like.

### Example 1

To further investigate the tuning property of the photodetector 10. The responsivity spectra of the photodetector 10 under different tuning conditions is measured. An example tuning spectrum is shown in FIG. 9. The photodetector 10 responsivity spectrum is plotted against the wavelength. At the blue shift side by MEMS structure 32 tuning, the tuning voltage is increased from 0V to 6.1V. The corresponding peak photocurrent wavelength is shifted from 1554 nm to 1521 nm, giving 34 nm tuning range. At the red shift side with thermal tuning, the device temperature is increased from 15° C. to 75° C. and another 6 nm tuning range added. The line width of the Example 1 embodiment is 1.1 nm and can be much smaller in the range of 0.2-0.8 nm. Parameters to be optimized would be the reflection of the coupling mirror and the absorption of the active region.

### Example 2

The tuning range of the photodetector 10 can be improved by designing the cavity reflector, which can be the first or second reflector 12 and 14, respectfully to have the wider high reflectivity bandwidth. For example, the second reflector 14, can be an HCG reflector instead of a DBR. Additionally, because an HCG reflector has a much smaller penetration depth than a DBR reflector, the total cavity 16 length is greatly reduced, which as a non-limiting example can be a reduction by 1 to 10 Lambda, and the tuning efficiency enhanced, which as a non-limiting example, the enhancement of the tuning is between 0.02 and 0.3 nm laser/nm mechanical movement. In another embodiment, by designing the MEMS structure 32 junction to have a higher break down voltage, as a non-limiting example 30-300 V, by optimizing the doping concentration, doping type, material type, and the like, a higher tuning voltage can be applied, as a non-limiting example, 30-100 V. Therefore, the MEMS spring constant can be stiffer, which as a non-limiting example can have k<1, in order to achieve a faster tuning speed with the same tuning range.

### Example 3

As a non-limiting example, the error free detection for 2.5 Gbps signal has been tested and the eye diagram is shown in FIG. 10.

From the description herein, it will be appreciated that that the present disclosure also encompasses embodiments which include, but are not limited to, the following:

1. A photodetector, comprising: a high contrast grating (HCG) reflector first reflector that has a two dimensional periodic structure, the two dimensional structure being a periodic structure that is a symmetric structure with periodic repeating, with the symmetrical structure providing that polarization modes of light are undistinguishable, and a second reflector in an opposing relationship to the first reflector; a tunable optical cavity between the first and second reflectors; an active region positioned in the cavity between the first and second reflectors, the photodetector being polarization independent; and an MQW light absorber that converts light to electrons.

2. The photodetector of any preceding embodiment, wherein the HCG has a 98 to 99 percent peak reflection.

3. The photodetector of any preceding embodiment, wherein the HCG has a peak reflection sufficient for detecting responsitivity, the higher the responsitivity the higher the conversion of light to electrons.

4. The photodetector of any preceding embodiment, wherein if the reflectivity is too high, incoming light is mostly reflected and the responsitivity is low, and when the reflectivity is too low the cavity is too weak to contain the light and absorb the light and the responsivity is low.

5. The photodetector of any preceding embodiment, wherein the HCG peak reflection is in the range of 98% to 99%, and a reflection bandwidth Δλ/λ is from 2% to 15%.

6. The photodetector of any preceding embodiment, wherein the HCG has a reflection band sufficient to have for band detection, at least one of: a full Cat 1530 to 1565 nm, a full L at 1565 to 1625 nm and a full S at 1460 to 1530 nm.

7. The photodetector of any preceding embodiment, wherein the photodetector has a sufficiently a signal to noise ratio to provide for detecting responsitivity.

8. The photodetector of any preceding embodiment, wherein the detecting responsitivity is in the range of at least 0.5 A/W.

9. The photodetector of any preceding embodiment, wherein the active region provides for sufficient absorption to be a detector with a responsitivity of at least 0.5 A/W.

10. The photodetector of any preceding embodiment, wherein the sufficient absorption with an MQW thickness of 6 to 12 nm.

11. The photodetector of any preceding embodiment, wherein the active region includes an MQW with a thickness of 6 to 12 nm.

12. The photodetector of any preceding embodiment, wherein the photodetector uses a reverse bias that is a negative voltage, wherein a positive voltage is applied on a photo current contact and a negative voltage is applied on an intracavity contact.

13. The photodetector of any preceding embodiment, wherein the photodetector detects light and converts photons to electrons with the MQW absorbing light, and energy in the light is converted to separate electrons and holes that are collected by contact and form current.

14. The photodetector of any preceding embodiment, wherein the active region is positioned in the cavity at an optical field anti-node position in the cavity.

15. The photodetector of any preceding embodiment, wherein the second reflector is a DBR.

16. The photodetector of any preceding embodiment, wherein the second reflector is a semiconductor or dielectric DBR.

17. The photodetector of any preceding embodiment, wherein the second reflector is a metal reflector.

18. The photodetector of any preceding embodiment, wherein the first reflector includes a one dimensional grid of materials.

19. The photodetector of any preceding embodiment, wherein the first reflector includes a two dimensional grid of materials.

20. The photodetector of any preceding embodiment, wherein the first reflector is non-periodic to achieve a desired optical mode shape inside or outside of the cavity.

21. The photodetector of any preceding embodiment, wherein the second reflector is an HCG.

22. The photodetector of any preceding embodiment, wherein the HCG is not polarization dependent.

23. The photodetector of any preceding embodiment, wherein the HCG is polarization dependent.

24. The photodetector of any preceding embodiment, wherein the active region is a multiple quantum well structure.

25. The photodetector of any preceding embodiment, wherein the active region is a double heterostructure action region.

26. The photodetector of any preceding embodiment, wherein the active region is at an anti-node of the optical field.

27. The photodetector of any preceding embodiment, wherein the first reflector is actuated by a light absorption structure.

28. The photodetector of any preceding embodiment, wherein the cavity is a Fabry-Perot cavity.

29. The photodetector of any preceding embodiment, wherein the first reflector is electrostatically actuatable.

30. The photodetector of any preceding embodiment, wherein the active region is within the Fabry-Perot cavity as a light absorbing layer.

31. The photodetector of any preceding embodiment, wherein the active region is below the Fabry-Perot as a light absorbing layer.

32. The photodetector of any preceding embodiment, wherein the photodetector is a tunable photodetector.

33. The photodetector of any preceding embodiment, further comprising: an embedded tunnel junction is placed inside the cavity to remove p-doped materials, to reduce free-carrier absorption.

34. The photodetector of any preceding embodiment, wherein the tunnel junction is placed at a node of the optical cavity to minimize its overlap with the optical field.

35. The photodetector of any preceding embodiment, wherein the active region is on a substrate of GaAs.

36. The photodetector of any preceding embodiment, wherein the active region is on a substrate of InP.

37. The photodetector of any preceding embodiment, wherein the active region is on a substrate of GaN.

38. The photodetector of any preceding embodiment, wherein the active region is on a substrate of GaP.

39. The photodetector of any preceding embodiment, wherein the photodetector is used in at least one of: a WDM network to select wavelength of interest; in a PON; as an optical wavemeter; as a spectrometer; as an optical spectrum analyzer in medical diagnostics; in a biochemical sensing application; with an industrial process control system; and with an environmental monitoring system.

40. The photodetector of any preceding embodiment, wherein the photodetector is used in concert with a TIA to provide an amplified signal.

41. The photodetector of any preceding embodiment, wherein the DBR is made of semiconductor materials.

42. The photodetector of any preceding embodiment, wherein the DBR is made of dielectric materials.

43. The photodetector of any preceding embodiment, wherein the DBR is made of metal in combination with semiconductor or dielectric materials.

44. The photodetector of any preceding embodiment, wherein the second reflector is metal.

45. The photodetector of any preceding embodiment, wherein the HCG is configured to act as a lens.

46. The photodetector of any preceding embodiment, wherein the photodetector configured to recover an analog data signal.

47. The photodetector of any preceding embodiment, wherein the photodetector is configured to recover a digital data signal.

48. The photodetector of any preceding embodiment, wherein the photodetector is incorporated with at least one of, optical and electrical elements to calibrate a wavelength of the photodetector.

49. The photodetector of any preceding embodiment, wherein the photodetector is configured to tuned to either red or blue off its center wavelength.

The foregoing description of various embodiments of the claimed subject matter has been provided for the purposes of illustration and description. It is not intended to be exhaustive or to limit the claimed subject matter to the precise forms disclosed. Many modifications and variations will be apparent to the practitioner skilled in the art. Particularly, while the concept “component” is used in the embodiments of the systems and methods described above, it will be evident that such concept can be interchangeably used with equivalent concepts such as, class, method, type, interface, module, object model, and other suitable concepts. Embodiments were chosen and described in order to best describe the principles of the invention and its practical application, thereby enabling others skilled in the relevant art to understand the claimed subject matter, the various embodiments and with various modifications that are suited to the particular use contemplated.

In the claims, reference to an element in the singular is not intended to mean “one and only one” unless explicitly so stated, but rather “one or more.” All structural, chemical, and functional equivalents to the elements of the disclosed embodiments that are known to those of ordinary skill in the art are expressly incorporated herein by reference and are intended to be encompassed by the present claims. Furthermore, no element, component, or method step in the present disclosure is intended to be dedicated to the public regardless of whether the element, component, or method step is explicitly recited in the claims. No claim element herein is to be construed as a “means plus function” element unless the element is expressly recited using the phrase “means for”. No claim element herein is to be construed as a “step plus function” element unless the element is expressly recited using the phrase “step for”.

What is claimed is:

1. A photodetector, comprising:
a high contrast grating (HCG) reflector first reflector that has a two dimensional periodic structure, the two dimensional structure being a periodic structure that is a symmetric structure with periodic repeating, with the symmetrical structure providing that polarization modes of light are undistinguishable, and a second reflector in an opposing relationship to the first reflector;
a tunable optical cavity between the first and second reflectors;
an active region positioned in the cavity between the first and second reflectors, the photodetector being polarization independent; and
an MQW light absorber that converts light to electrons.

2. The photodetector of claim 1, wherein the HCG has a 98 to 99 percent peak reflection.

3. The photodetector of claim 1, wherein the HCG has a peak reflection sufficient for detecting responsitivity, the higher the responsitivity the higher the conversion of light to electrons.

4. The photodetector of claim 3, wherein if the reflectivity is too high, incoming light is mostly reflected and the responsitivity is low, and when the reflectivity is too low the cavity is too weak to contain the light and absorb the light and the responsivity is low.

5. The photodetector of claim 3, wherein the HCG peak reflection is in the range of 98% to 99%, and a reflection bandwidth Δλ/λ is from 2% to 15%.

6. The photodetector of claim 1, wherein the HCG has a reflection band sufficient to have for band detection, at least one of: a full C at 1530 to 1565 nm, a full L at 1565 to 1625 nm and a full Sat 1460 to 1530 nm.

7. The photodetector of claim 1, wherein the photodetector has a sufficiently a signal to noise ratio to provide for detecting responsitivity.

8. The photodetector of claim 7, wherein the detecting responsitivity is in the range of at least 0.5 A/W.

9. The photodetector of claim 1, wherein the active region provides for sufficient absorption to be a detector with a responsitivity of at least 0.5 A/W.

10. The photodetector of claim 9, wherein the sufficient absorption with an MQW thickness of 6 to 12 nm.

11. The photodetector of claim 1, wherein the active region includes an MQW with a thickness of 6 to 12 nm.

12. The photodetector of claim 1, wherein the photodetector uses a reverse bias that is a negative voltage, wherein a positive voltage is applied on a photo current contact and a negative voltage is applied on an intracavity contact.

13. The photodetector of claim 1, wherein the photodetector detects light and converts photons to electrons with the MQW absorbing light, and energy in the light is converted to separate electrons and holes that are collected by contact and form current.

14. The photodetector of claim 1, wherein the active region is positioned in the cavity at an optical field anti-node position in the cavity.

15. The photodetector of claim 1, wherein the second reflector is a DBR.

16. The photodetector of claim 1, wherein the second reflector is a semiconductor or dielectric DBR.

17. The photodetector of claim 1, wherein the second reflector is a metal reflector.

18. The photodetector of claim 1, wherein the first reflector includes a one dimensional grid of materials.

19. The photodetector of claim 1, wherein the first reflector includes a two dimensional grid of materials.

20. The photodetector of claim 1, wherein the first reflector is non-periodic to achieve a desired optical mode shape inside or outside of the cavity.

21. The photodetector of claim 1, wherein the second reflector is an HCG.

22. The photodetector of claim 1, wherein the HCG is not polarization dependent.

23. The photodetector of claim 1, wherein the HCG is polarization dependent.

24. The photodetector of claim 1, wherein the active region is a multiple quantum well structure.

25. The photodetector of claim 1, wherein the active region is a double heterostructure action region.

26. The photodetector of claim 1, wherein the active region is at an anti-node of the optical field.

27. The photodetector of claim 1, wherein the first reflector is actuated by a light absorption structure.

28. The photodetector of claim 1, wherein the cavity is a Fabry-Perot cavity.

29. The photodetector of claim 1, wherein the first reflector is electrostatically actuatable.

30. The photodetector of claim 1, wherein the active region is within the Fabry-Perot cavity as a light absorbing layer.

31. The photodetector of claim 1, wherein the active region is below the Fabry-Perot as a light absorbing layer.

32. The photodetector of claim 1, wherein the photodetector is a tunable photodetector.

33. The photodetector of claim 1, further comprising:
an embedded tunnel junction is placed inside the cavity to remove p-doped materials, to reduce free-carrier absorption.

34. The photodetector of claim 1, wherein the tunnel junction is placed at a node of the optical cavity to minimize its overlap with the optical field.

35. The photodetector of claim 1, wherein the active region is on a substrate of GaAs.

36. The photodetector of claim 1, wherein the active region is on a substrate of InP.

37. The photodetector of claim 1, wherein the active region is on a substrate of GaN.

38. The photodetector of claim 1, wherein the active region is on a substrate of GaP.

39. The photodetector of claim 1, wherein the photodetector is used in at least one of: a WDM network to select wavelength of interest; in a PON; as an optical wavemeter; as a spectrometer; as an optical spectrum analyzer in medical diagnostics; in a biochemical sensing application; with an industrial process control system; and with an environmental monitoring system.

40. The photodetector of claim 1, wherein the photodetector is used in concert with a TIA to provide an amplified signal.

41. The photodetector of claim 3, wherein the DBR is made of semiconductor materials.

42. The photodetector of claim 3, wherein the DBR is made of dielectric materials.

43. The photodetector of claim 3, wherein the DBR is made of metal in combination with semiconductor or dielectric materials.

44. The photodetector of claim 1, wherein the second reflector is metal.

45. The photodetector of claim 1, wherein the HCG is configured to act as a lens.

46. The photodetector of claim 1, wherein the photodetector configured to recover an analog data signal.

47. The photodetector of claim 1, wherein the photodetector is configured to recover a digital data signal.

48. The photodetector of claim 1, wherein the photodetector is incorporated with at least one of, optical and electrical elements to calibrate a wavelength of the photodetector.

49. The photodetector of claim 1, wherein the photodetector is configured to tuned to either red or blue off its center wavelength.
